(19) United States
(12) Patent Application Publication
(10) Pub. No.: US 2013/0301355 A1
(43) Pub. Date: Nov. 14, 2013

(54) EEPROM MEMORY UNIT AND EEPROM MEMORY DEVICE

(71) Applicant: Guangiun Yang, Shanghai (CN)

(72) Inventor: Guangiun Yang, Shanghai (CN)

(73) Assignee: Grace Semiconductor Manufacturing Corporation, Shanghai (CN)

(21) Appl. No.: 13/846,549

(22) Filed: Mar. 18, 2013

(30) Foreign Application Priority Data
May 9, 2012 (CN) 201210143432.9

(51) Int. Cl. G11C 16/02

(52) U.S. Cl. CPC G11C 16/02
USPC 365/185.18

(57) ABSTRACT

An EEPROM memory unit is disclosed. The EEPROM memory unit includes a first memory cell, a second memory cell, and a word line controller. The first memory cell includes a source that is connected to a first bit line of the EEPROM memory unit and a drain that is connected to a source of the word line controller. The word line controller includes a drain that is connected to a source of the second memory cell. The second memory cell includes a drain that is connected to a second bit line of the EEPROM memory unit. An EEPROM memory device is also disclosed.

### CROSS-REFERENCES TO RELATED APPLICATIONS

This application claims the priority of Chinese Patent Application Number 201210143432.9, filed on May 9, 2012, the entire contents of which are incorporated herein by reference.

### TECHNICAL FIELD

The present invention relates in general to the field of semiconductor fabrication, and more particularly, to an electrically erasable programmable read-only memory (EEPROM) memory unit and an EEPROM memory device.

### BACKGROUND

Electrically erasable programmable read-only memory (EEPROM) is a type of semiconductor memory that will not lose data stored in it when the power is removed.

Flash memory is another type of non-volatile memory. It is a modified EEPROM memory and its most distinguishing feature is that it must be erased on a block-by-block basis (the size of a block varies according to the manufacturer). In contrast, an EEPROM memory can only be erased on a byte-by-byte basis.

There is a need for a memory device which possesses advantages of both an EEPROM memory and a flash memory.

### SUMMARY OF THE INVENTION

The present invention addresses the foregoing prior art drawbacks by providing a memory device which possesses advantages of both an EEPROM memory and a flash memory.

In a first aspect of the present invention, it is provided an EEPROM memory unit including a first memory cell, a second memory cell, and a word line controller, wherein the first memory cell includes a source connected to a first bit line of the EEPROM memory unit and a drain connected to a source of the word line controller, wherein the word line controller includes a drain connected to a source of the second memory cell; and wherein the second memory cell includes a drain connected to a second bit line of the EEPROM memory unit.

In one embodiment, the first memory cell includes a first control gate and the second memory cell includes a second control gate. Moreover, the word line controller includes a gate connected to a word line of the EEPROM memory unit.

In another embodiment, only one of the first and second memory cells is configured to be in use and the other one serves as a spare memory cell.

In still another embodiment, the first and second memory cells are configured to be erased at the same time.

In a second aspect of the present invention, it is provided an EEPROM memory device, including: a plurality of byte arrays, each of which includes a plurality of above-mentioned EEPROM memory units arranged in an array, among which: all the EEPROM memory units arranged in a same row are configured to have their first control gates interconnected, their second control gates interconnected and their word lines interconnected; all the EEPROM memory units arranged in a same column are configured to have their first bit lines interconnected and their second bit lines interconnected; and a word-line/control-gate switching unit connected to each of the first control gates, second control gates and word lines of each byte array.

In one embodiment, the word-line/control-gate switching unit is configured to control each of the first control gates, second control gates and word lines of each byte array during programming and erasing operations so as to separate the plurality of byte arrays from one another.

In another embodiment, the word-line/control-gate switching unit includes a transistor array.

Compared to a traditional flash memory unit, as a spare memory cell can be used to replace the main memory cell in an EEPROM memory unit or in each EEPROM memory unit of an EEPROM memory device according to the present invention, the cycling endurance of the EEPROM memory unit is doubled without any deterioration in its other performance.

### BRIEF DESCRIPTION OF THE DRAWINGS

To provide a more complete understanding of the present invention as well as its advantages and features, reference is made to the following detailed description on exemplary embodiments, taken in conjunction with the accompanying drawings, in which:

FIG. 1 schematically illustrates a structure of an EEPROM memory unit according to one embodiment of the present invention;

FIG. 2 schematically illustrates the interconnection structure of a plurality of EEPROM memory units according to one embodiment of the present invention; and

FIG. 3 schematically illustrates an EEPROM memory device according to one embodiment of the present invention.

Note that the accompanying drawings for showing structures may not be to scale, and are incorporated to depict the invention only. Therefore, the drawings should not be construed in any manner to limit the scope of the invention. In the drawings, the same or similar reference numbers represent the same or similar elements.

### DETAILED DESCRIPTION

The present invention will be clearer and easier to be understood upon reading the following description of specific embodiments with reference to the accompanying drawings.

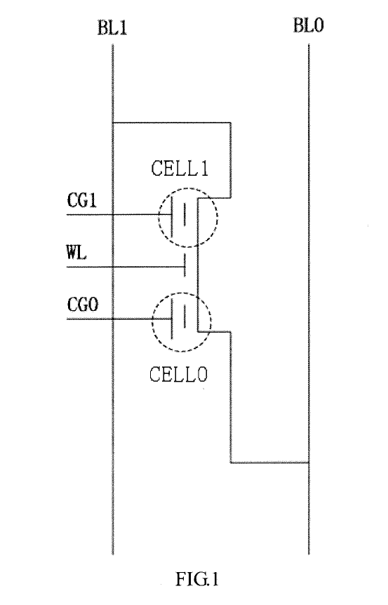

FIG. 1 schematically illustrates a structure of an EEPROM memory unit according to one embodiment of the present invention.

As illustrated, the EEPROM memory unit in this embodiment includes a first memory cell CELL1, a second memory cell CELL0, and a word line controller. A source of the first memory cell CELL1 is connected to a first bit line BL1 of the EEPROM memory unit and a drain of the first memory cell CELL1 is connected to a source of the word line controller. A drain of the word line controller is connected to a source of the second memory cell CELL0 and a drain of the second memory cell CELL0 is connected to a second bit line BL0 of the EEPROM memory unit.

Such a structure provides a flash memory unit structure having double memory cells.

Further, in the EEPROM memory unit of this embodiment, a gate of the first memory cell CELL1 serves as a first control gate CG1; a gate of the second memory cell CELL0 serves as a second control gate CG2; and a gate of the word line controller is connected to a word line WL of the EEPROM memory unit.

In the EEPROM memory unit in this embodiment, the second memory cell CELLO together with the first memory cell CELL1 may function, as a whole, as one memory cell.

Specifically, in a normal operation state (or referred to as a normal operation mode), it may be configured that only one of the first memory cell CELL1 and the second memory cell CELL0 (for example, only the second memory cell CELL0) serves as a main memory cell while the other one (i.e., the first memory cell CELL1 in this example) serves as a spare memory cell. Thus, in this case, all programming and reading operations are performed only to the second memory cell CELL0.

Moreover, it may be further configured that the user switches to use the other memory cell (i.e., the spare memory cell in this example) when a current flowing in the memory cell in use is not enough.

Furthermore, it may also be selectively configured that the spare memory cell is never used so that reading operations are always performed to the same main memory cell and in the same direction.

In one preferred embodiment, it may be configured that the first memory cell CELL1 and the second memory cell CELL0 are always erased at the same time. As states of these two memory cells will affect each other and only when both the two memory cells are in an erasing state (i.e., they are in a state of “11”) can a maximum current be obtained, in this embodiment, it may be configured that when the associated memory unit is in an erasing state, its two memory cells are always set to a state of “11”.

Cycling endurance serves to measure the maximum times that a memory unit can be successfully programmed (i.e., set to a state of “0”) and then erased (i.e., set to a state of “1”). Compared to a traditional flash memory unit, as the spare memory cell can be used to replace the main memory cell in the EEPROM memory unit according to embodiments of the present invention, its cycling endurance is doubled without any deterioration in its other performance.

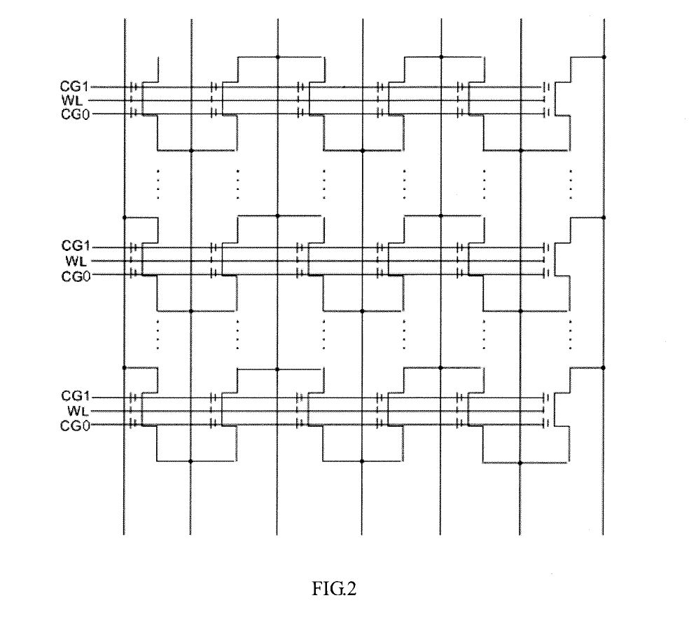

FIG. 2 schematically illustrates the interconnection structure of a plurality of EEPROM memory units according to one embodiment of the present invention.

As illustrated, a plurality of EEPROM memory units according to the embodiment shown in FIG. 1 are interconnected into an array.

Specifically, EEPROM memory units arranged in a same row have their first control gates CG1 interconnected, their second control gates CG0 interconnected and their word lines WL interconnected.

Moreover, as shown in FIG. 2, EEPROM memory units arranged in a same column have their first bit lines BL1 interconnected and their second bit lines BL0 interconnected.

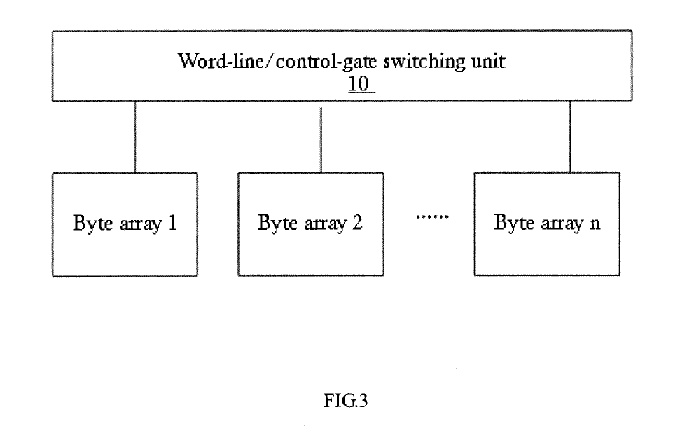

FIG. 3 schematically illustrates an EEPROM memory device according to one embodiment of the present invention.

As illustrated, in this embodiment, the EEPROM memory device includes a plurality of byte arrays (including byte array 1, byte array 2, . . . , and byte array n) and a word-line/control-gate switching unit 10 that is connected to each of the byte arrays. Specifically, the word-line/control-gate switching unit 10 is connected to each of the first control gates CG1, second control gates CG0 and word lines WL of each byte array.

Each memory unit of each byte array (i.e., byte array 1, byte array 2, . . . , or byte array n) is an EEPROM memory unit according to the embodiment shown in FIG.1. In addition, memory units of each byte array (i.e., byte array 1, byte array 2, . . . , or byte array n) are interconnected into an array in a way as shown in FIG. 2.

Furthermore, the word-line/control-gate switching unit 10 may be configured to control each of the first control gates CG1, second control gates CG0 and word lines WL of each byte array during programming and erasing operations so as to separate the plurality of byte arrays from one another.

In an exemplary embodiment, the word-line/control-gate switching unit 10 may be designed as a transistor array so that it may have a relatively simple structure and a small size.

Similarly, as the spare memory cell is additionally arranged for the main memory cell in each EEPROM memory unit of the EEPROM memory device according to embodiments of the present invention, compared to a traditional flash memory unit, cycling endurance of EEPROM memory units of the EEPROM memory device is doubled without any deterioration in their other performance.

While this invention has been particularly shown and described with respect to foregoing preferred embodiments, it will be understood that they are not intended to limit the scope of the present invention in any way. Accordingly, those skilled in the art will appreciate that various alternative and equivalent embodiments can be made based on the disclosure. In addition, those skilled in the art can make various modifications and variations of the present invention without departing from the scope of the invention. Thus, it is intended that the present invention covers all such changes, variations and modifications within the scope of the present invention.

What is claimed is:

1. An EEPROM memory unit, comprising a first memory cell, a second memory cell, and a word line controller, wherein the first memory cell comprises a source connected to a first bit line of the EEPROM memory unit and a drain connected to a source of the word line controller, the word line controller comprises a drain connected to a source of the second memory cell, and the second memory cell comprises a drain connected to a second bit line of the EEPROM memory unit.

2. The EEPROM memory unit according to claim 1, wherein the first memory cell comprises a first control gate; the second memory cell comprises a second control gate; and the word line controller comprises a gate connected to a word line of the EEPROM memory unit.

3. The EEPROM memory unit according to claim 2, wherein one of the first memory cell and the second memory cell is configured as a spare memory cell.

4. The EEPROM memory unit according to claim 2, wherein the first memory cell and the second memory cell are configured to be erased at the same time.

5. An EEPROM memory device, comprising:
a plurality of byte arrays, each byte array comprising a plurality of EEPROM memory units according to claim 2, being arranged in an array, and a word-line/control-gate switching unit connected to each of the first control gates, second control gates and word lines of each byte array.

6. The EEPROM memory device according to claim 5, wherein the word-line/control-gate switching unit is configured to control each of the first control gates, second control gates and word lines of each byte array during programming and erasing operations so as to separate the plurality of byte arrays from one another.

7. The EEPROM memory device according to claim 5, wherein the word-line/control-gate switching unit comprises a transistor array.

8. An EEPROM memory device, comprising:
a plurality of byte arrays, each byte array comprising a plurality of EEPROM memory units according to claim 2 being arranged in an array of a plurality of rows and a plurality of columns, wherein the EEPROM memory units arranged in a same row are configured to have the first control gates interconnected, the second control gates interconnected and the word lines interconnected; and the EEPROM memory units arranged in a same column are configured to have the first bit lines interconnected and the second bit lines interconnected; and
a word-line/control-gate switching unit connected to each of the first control gates, second control gates and word lines of each byte array.

9. The EEPROM memory device according to claim 8, wherein the word-line/control-gate switching unit is configured to control each of the first control gates, second control gates and word lines of each byte array during programming and erasing operations so as to separate the plurality of byte arrays from one another.

10. The EEPROM memory device according to claim 8, wherein the word-line/control-gate switching unit comprises a transistor array.
